(19) United States
(12) Patent Application Publication
(10) Pub. No.: US 2021/0013374 A1
(43) Pub. Date: Jan. 14, 2021

(54) III-NITRIDE OPTOELECTRONIC DEVICES AND METHOD OF PRODUCTION

(71) Applicant: KING ABDULLAH UNIVERSITY OF SCIENCE AND TECHNOLOGY, Thuwal (SA)

(72) Inventors: Daisuke IIDA, Thuwal (SA); Kazuhiro OHKAWA, Thuwal (SA)

(21) Appl. No.: 16/980,186

(22) PCT Filed: Feb. 6, 2019
(86) PCT No.: PCT/IB2019/050957

§ 371 Date: Sep. 11, 2020

Related U.S. Application Data
(60) Provisional application No. 62/723,713, filed on Aug. 28, 2018.
(60) Provisional application No. 62/644,777, filed on Mar. 19, 2018.

(51) Int. Cl. H01L 33/32; H01L 33/28; H01L 33/50; H01L 33/00

(52) U.S. Cl. CPC H01L 33/32; H01L 33/0075; H01L 33/502; H01L 33/28

(57) ABSTRACT

An optoelectronic device includes an oxide substrate, an oxide epitaxial layer arranged on the oxide substrate, and a III-nitride active layer arranged on the oxide epitaxial substrate.

### CROSS-REFERENCE TO RELATED APPLICATIONS

This application claims priority to U.S. Provisional Patent Application No. 62/644,777, filed on Mar. 19, 2018, entitled “NITRIDE EPITAXIAL GROWTH WITH OXIDE BUFFER LAYER BY NITRIDE-OXIDE MOVPE,” and U.S. Provisional Patent Application No. 62/723,713, filed on Aug. 28, 2018, entitled “Ill-NITRIDE OPTOELECTRONIC DEVICES AND METHOD OF PRODUCTION,” the disclosures of which are incorporated herein by reference in their entirety.

### BACKGROUND

### Technical Field

Embodiments of the disclosed subject matter generally relate III-nitride optoelectronic devices having an oxide substrate and oxide epitaxial layer on which a III-nitride active layer is arranged.

### Discussion of the Background

III-nitride semiconductors (aluminum nitride (AIN), gallium nitride (GaN), indium nitride (InN), boron nitride (BN) and their alloys) have emerged as key materials for fabricating optoelectronic devices, such as light emitting diodes (LEDs), laser diodes, photodetectors, etc. III-nitride semiconductors are typically formed on sapphire substrates due to the high temperature stability, heat dissipation and chemical properties of sapphire substrates. However, due to the large lattice mismatch between the sapphire substrate and the III-nitride active layer, a device having a III-nitride active layer formed on a sapphire substrate has reduced efficiency. This reduced efficiency can be significant in many applications of III-nitride optoelectronic devices, which are often intended for applications in which power efficiency is important, such as in battery-powered devices.

One way to address the lattice mismatch between the substrate and the III-nitride active layer is form a gallium nitride active layer on a zinc oxide (ZnO) substrate. Compared to forming a gallium nitride active layer on a sapphire substrate, which has a 16% lattice mismatch, a gallium nitride active layer on a zinc oxide substrate has a −2.1% lattice mismatch. The lattice mismatch can be substantially eliminated by using an indium gallium nitride active layer having the composition of In_{0.19}Ga_{0.81}N. Although a device having a gallium nitride active layer on a zinc oxide substrate reduces lattice mismatch and an indium gallium nitride active layer on a zinc oxide substrate substantially eliminates lattice mismatch, gallium nitride or indium gallium nitride active layers have low crystal quality and a rough surface due to damage on the top surface of the zinc oxide substrate on which the active layer is formed.

One way to reduce the damage to the zinc oxide substrate is to form a low-temperature gallium nitride (or indium gallium nitride) buffer layer on the zinc oxide substrate and then form the gallium nitride active layer on the low-temperature gallium nitride (or indium gallium nitride) buffer layer. Although the low-temperature gallium nitride buffer layer can protect the surface of the zinc oxide substrate during growth of the gallium nitride active layer, the damage on the top surface of the zinc oxide substrate results in the gallium nitride (or indium gallium nitride) buffer layer and the gallium nitride (or indium gallium nitride) active layer having low crystal quality and rough surfaces, which reduces the efficiency of the device.

Thus, it would be desirable to provide III-nitride optoelectronic devices having a lower lattice mismatch between the substrate and the III-nitride active layer while providing a suitable base for the formation of the III-nitride active layer.

### SUMMARY

According to an embodiment, there is an optoelectronic device, which includes an oxide substrate, an oxide epitaxial layer arranged on the oxide substrate, and a III-nitride active layer arranged on the oxide epitaxial substrate.

According to another embodiment, there is a method of forming an optoelectronic device. An oxide epitaxial layer is formed on an oxide substrate. A III-nitride active layer is formed on the oxide epitaxial layer.

According to a further embodiment, there is a method of forming an optoelectronic device. A composition of an oxide substrate is determined. A composition of an oxide epitaxial layer is determined based on the determined composition of the oxide substrate. A composition of a III-nitride active layer is determined based on the determined composition of the oxide epitaxial layer to minimize a lattice mismatch between the III-nitride active layer and the oxide epitaxial layer. The optoelectronic device having an oxide epitaxial layer on the oxide substrate and the III-nitride active layer on the oxide epitaxial layer is formed using the determined compositions of the oxide substrate, oxide epitaxial layer, and III-nitride active layer.

### BRIEF DESCRIPTION OF THE DRAWINGS

The accompanying drawings, which are incorporated in and constitute a part of the specification, illustrate one or more embodiments and, together with the description, explain these embodiments. In the drawings:

FIG. 1 is a block diagram of a III-nitride optoelectronic device according to embodiments;

FIG. 2 is a flowchart of a method of forming a III-nitride optoelectronic device according to embodiments;

FIG. 3 is a block diagram of a III-nitride optoelectronic device according to embodiments;

FIG. 4 is a block diagram of a III-nitride optoelectronic device according to embodiments;

FIG. 5 is graph of the strain of indium gallium nitride (InGaN) layers with various indium contents according to embodiments;

FIG. 6 is a graph of emission peak wavelengths of III-nitride optoelectronic devices according to embodiments; and

FIG. 7 is a flowchart of a method of forming a III-nitride optoelectronic device according to embodiments.

### DETAILED DESCRIPTION

The following description of the exemplary embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to the terminology and structure of III-nitride optoelectronic devices.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

FIG. 1 is a block diagram of a III-nitride optoelectronic device according to embodiments. The III-nitride optoelectronic device 100 includes an oxide substrate 105, an oxide epitaxial layer 110 arranged on the oxide substrate 105, and a III-nitride active layer arranged on the oxide epitaxial layer 110. The III-nitride optoelectronic device 100 can be a light emitting diode (LED), laser diode, solar cell, photocatalyst, photodetector, or the like.

The III-nitride active layer 115 can comprise gallium nitride, indium nitride, aluminum nitride and alloys of these nitrides, i.e., gallium indium nitride, gallium aluminum nitride, indium aluminum nitride, and gallium, indium, aluminum nitride. The table below describes various combinations of various combinations of oxide substrates 105 and oxide epitaxial layers 110 that can be used with the aforementioned compositions of the III-nitride active layer 115:

| Oxide Substrate 105 | Oxide Epitaxial Layers 110 |
|---|---|
| Zinc Oxide (ZnO) | At least one of Magnesium (Mg), Calcium |
| | (Ca), Zinc (Zn), and Cadmium (Cd); and |
| | An Oxide (O) |
| Scandium Aluminum | At least one of Magnesium, Aluminum |
| Magnesium Oxide | (Al), Calcium (Ca), Scandium (Sc), Zinc |
| (ScAlMgO₄) | (Zn), Gallium (Ga), Strontium (Sr), |
| | Yttrium (Y), Cadmium (Cd), and Indium |
| | (In); and |
| | An Oxide (O₄) |
| Gallium Oxide | At least one of Aluminum (Al₂), Gallium |
| (Ga₂O₃) | (Ga₂), and Indium (In₂); and |
| | An Oxide (O₃) |
| Magnesium Oxide | At least one of Magnesium (Mg), Calcium |
| (MgO) | (Ca), Zinc (Z), Strontium (Sr), and |
| | Cadmium (Cd); and |
| | An Oxide (O) |
| Magnesium Aluminum | At least one of Magnesium (Mg), Calcium |
| Oxide (MgAl₂O₄) | (Ca), and Strontium (Sr); |
| | At least one of Aluminum (Al₂), Zinc (Zn₂), |
| | Gallium (Ga₂), Cadmium (Cd₂) and |
| | Aluminum (Al₂); and |
| | An Oxide (O₄) |
| Lithium Aluminum Oxide | At least one of Lithium (Li), Sodium (Na), |
| (LiAlO₂) | Aluminum (Al), Potassium (K), Gallium |
| | (Ga), Rubidium (Rb), and Indium (In); and |
| | An Oxide (O₂) |

The table above refers to “At least one of” to indicate that the epitaxial layer can be a non-alloy or an alloy. For example, for a zinc oxide substrate, the following epitaxial layers are possible: magnesium oxide (MgO), calcium oxide (CaO), zinc oxide (ZnO), cadmium oxide (CdO), zinc magnesium oxide (ZnₓMg₁₋ₓO), zinc magnesium cadmium oxide (ZnₓMg_{y}Cd_{1-x-y}O), etc. It will be recognized that this applies to all of the epitaxial layers in the table above.

All of the various combinations listed in the table above provide a combination of an oxide substrate and oxide epitaxial layer that results in minimal or no lattice mismatch (i.e., reduced strain or no strain) at the interface between the III-nitride active layer and the underlying layers. The minimal or no lattice mismatch at the interface is significantly less than the 16% lattice mismatch of a device having a III-nitride active layer on a sapphire substrate. As will be appreciated from the table above, the oxide substrate 105 and the oxide epitaxial layer can both comprise the same materials (e.g., a ZnO substrate 105 and a ZnO epitaxial layer 110), the oxide substrate 105 and the oxide epitaxial layer 110 can comprise oxide and one additional common material and the oxide substrate can include one material that is not present in the oxide epitaxial layer 110 (e.g., a magnesium aluminum oxide substrate 105 and a magnesium zinc oxide epitaxial layer 110), or the oxide substrate 105 and the oxide epitaxial layer can comprise different materials other than the oxide (e.g., a gallium oxide substrate 105 and an aluminum oxide epitaxial layer 110).

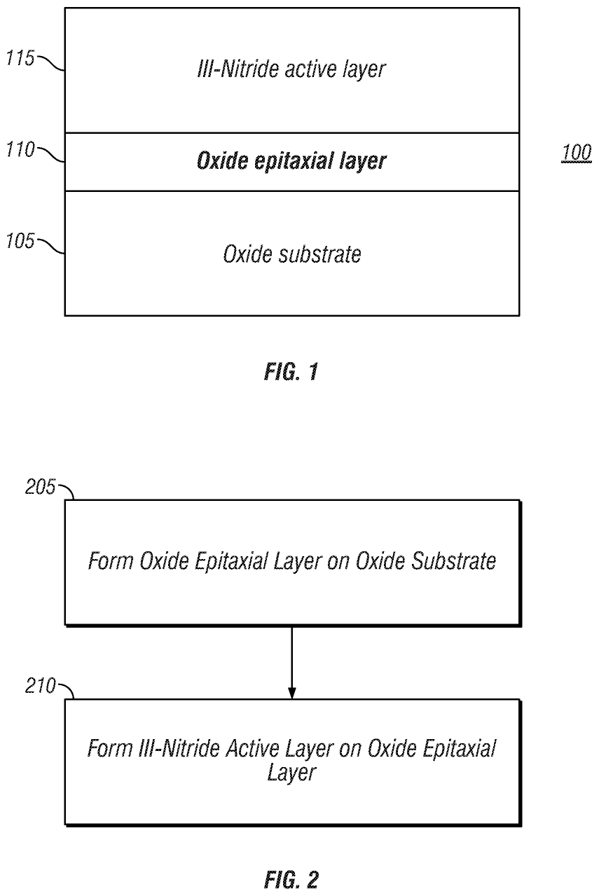

FIG. 2 is a flowchart of a method of forming a III-nitride optoelectronic device 100 according to embodiments. Initially, an oxide epitaxial layer 110 is formed on an oxide substrate 105 (step 205). A III-nitride active layer 115 is then formed on the oxide epitaxial layer 110 (step 210). The oxide substrate 105 can be formed during the same process as forming the oxide epitaxial layer 110 and the III-nitride active layer 115 or can be formed in a separate process. For example, the oxide substrate 105, oxide epitaxial layer 110, and III-nitride active layer 115 can be formed in a common growth chamber using metal-organic chemical vapor deposition (MOCVD), or any similar growth technique. This allows the III-nitride optoelectronic device 100 to be formed in a continuous growth process, which is advantageous because it minimizes contamination that can reduce the efficiency of the device.

When the oxide substrate 105 is formed separately from oxide epitaxial layer 110 and the III-nitride active layer 115, the heat and oxide used during formation of the oxide epitaxial layer 110 forms an atomically flat surface on the top of the oxide substrate 105 by annealing the top surface of the oxide substrate 105. This is significant because oxide substrates that are available for purchase (i.e., an oxide substrate formed in a different growth chamber than the remaining layers) are typically polished, which results in a thin layer of damage on the top surface of the oxide substrate, which can affect the formation of a high quality junction between the oxide epitaxial layer and the oxide substrate. Thus, forming an atomically flat surface on the top surface of the oxide substrate 105 by annealing that occurs during the formation of the oxide epitaxial layer 110 results in a high quality interface between the oxide substrate 105 and the oxide epitaxial layer 110, which produces a more efficient optoelectronic device. It should be recognized that the annealing requires an oxygen source, such as O₂, CO, CO₂, H₂O, CH₃OH, C₂H₅OH, C₃H₇OH, C₄H₉OH, etc.

In order to improve the conductivity of the oxide epitaxial layer, this layer can be subject to n-type doping during the formation of that layer using, for example, aluminum, gallium, indium, silicon, germanium, tin, etc.

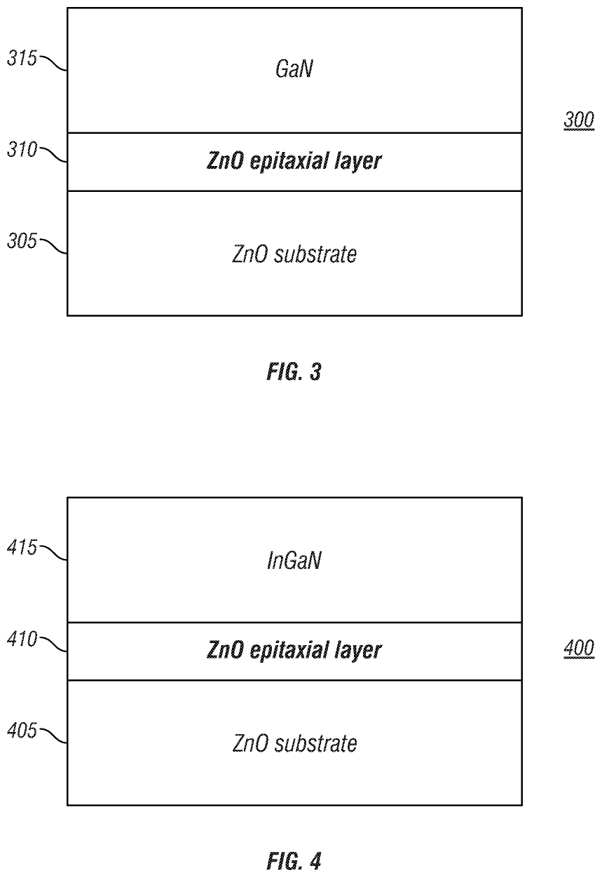

FIG. 3 is a block diagram of a III-nitride optoelectronic device according to embodiments. In the embodiment illustrated in FIG. 3, the optoelectronic device 300 includes a zinc oxide substrate 305 as the oxide substrate, a zinc oxide epitaxial layer 310 as the oxide epitaxial layer, and a gallium nitride active layer 315 as the III-nitride active layer 315.

The zinc oxide epitaxial layer 310 can be, for example, 10 to 10,000 nm thick, preferably 10 to 1,000 nm thick, and in one example is 300 nm thick. The gallium nitride active layer 315 can be, for example, 10 to 10,000 nm thick, preferably 100 to 3,000 nm thick, and in one example is 3 μm thick. Further, the conductivity of the zinc oxide epitaxial layer 310 can be increased by n-type doping, using, for example, aluminum, gallium, indium, silicon, germanium, tin, or the like, at a doping concentration of, for example, 1×10¹⁷ cm³ and 1×10²¹ cm³, and in one embodiment can be 1×10¹⁸ cm³. The gallium nitride active layer 315 is not intentionally doped, however, due to contaminants present during the growth process, the gallium nitride active layer may be unintentionally doped.

The growth temperatures used for certain III-nitride active layers can damage the underlying layers. For example, gallium nitride typically requires a growth temperature of approximately 1,000° C., whereas zinc oxide typically requires a growth temperature of approximately 600° C. Thus, the higher growth temperature of the gallium nitride active layer 315 can damage a zinc oxide epitaxial layer 310, which can reduce the performance of the optoelectronic device. This problem can be addressed by including indium in the III-nitride active layer. For example, an indium gallium nitride active layer can be grown at a temperature of approximately 600° C., which would minimize or eliminate any damage caused to the underlying zinc oxide epitaxial layer. An example of such a device is illustrated in FIG. 4. As illustrated, the optoelectronic device 400 includes a zinc oxide substrate 405 on which a zinc oxide epitaxial layer 410 is formed. An indium gallium nitride active layer 415 is formed on the zinc oxide epitaxial layer 410.

The zinc oxide epitaxial layer 410 can be, for example, 10 to 10,000 nm thick, preferably 10 to 1,000 nm thick, and in one example is 300 nm thick. The indium gallium nitride active layer 415 can be, for example, 10 to 10,000 nm thick, preferably 100 to 3,000 nm thick, and in one example is 200 nm thick. The indium gallium nitride layer can comprise In_{0.19}Ga_{0.81}N, in one example. In_{0.19}Ga_{0.81}N and zinc oxide are lattice matched, and thus there is no strain at the interface between the epitaxial layer 410 and the zinc oxide substrate 405. Further, the conductivity of the zinc oxide epitaxial layer 410 can increased by n-type doping, using, for example, aluminum, gallium, indium, silicon, germanium, tin, or the like, at a doping concentration of, for example, 1×10¹⁷ cm³ and 1×10²¹ cm³, and in one embodiment can be 1×10¹⁸ cm³. The indium gallium nitride active layer 315 is not intentionally doped, however, due to contaminants present during the growth process, the indium gallium nitride active layer may be unintentionally doped.

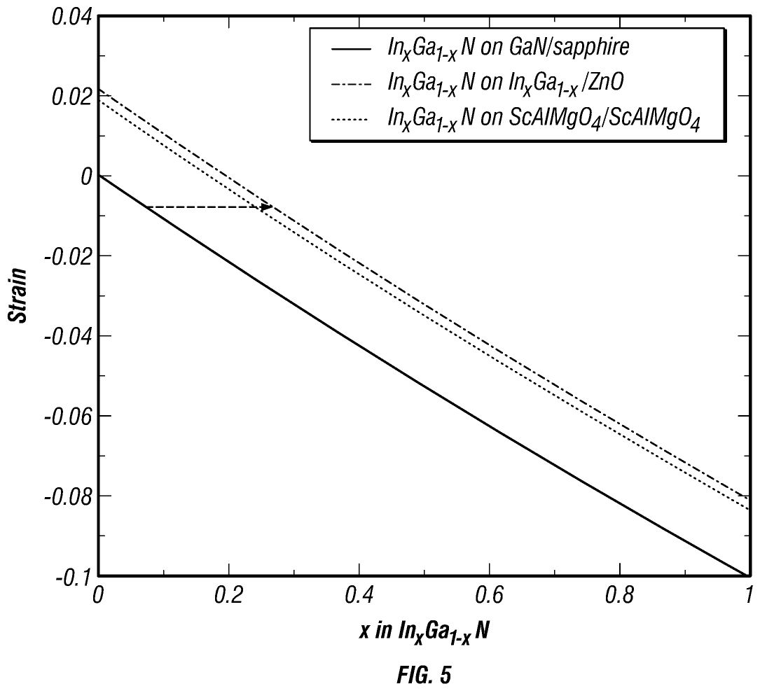

The use of indium in the III-nitride active layer has an additional advantage of being able to adjust the strain (i.e., the lattice mismatch) at the interface between the III-nitride layer and the underlying layers. Specifically, referring to FIG. 5, an optoelectronic device having a gallium oxide active layer with no indium (i.e., x=0) on a zinc oxide epitaxial layer and zinc oxide substrate has a strain of approximately 0.02. However, by adding approximately 0.19 of indium (i.e., In_{0.19}Ga_{0.81}N) the strain can be reduced to zero. Similarly, an optoelectronic device having gallium nitride active layer on a scandium aluminum magnesium oxide (ScAlMgO₄) epitaxial layer and a scandium aluminum magnesium oxide (ScAlMgO₄) has a strain of approximately 0.02, which can be reduced to zero by adding approximately 0.19 of indium to the gallium nitride active layer (i.e., In_{0.19}Ga_{0.81}N)

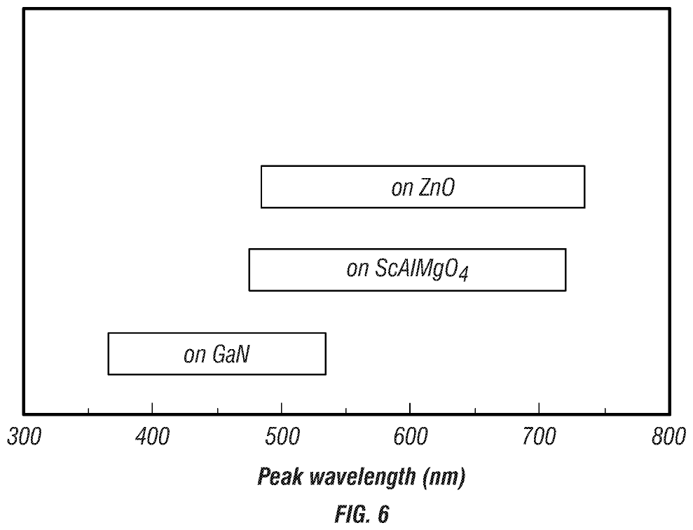

FIG. 6 is a graph of emission peak wavelengths of III-nitride optoelectronic devices according to embodiments in which the III-nitride active layer comprises InₓGa₁₋ₓA. The epitaxial layers in this figure are the same as those in FIG. 5. As illustrated, using an indium gallium nitride active layer on a zinc oxide or scandium aluminum magnesium oxide substrate, the range of possible peak wavelengths can be shifted compared to the range of peak wavelengths of a gallium nitride substrate.

The amount of indium in the III-nitride active layer adjusts the peak wavelength of the device. For example, a device having an In_{0.19}Ga_{0.81}N active layer on a zinc oxide epitaxial layer and a zinc oxide substrate produces a peak wavelength of 490 nm (i.e., a blue light emitting diode) with minimal strain, a device having an In_{0.27}Ga_{0.73}N active layer on a zinc oxide epitaxial layer and zinc oxide substrate produces a peak wavelength of 569 nm (i.e., a yellow light emitting diode) with minimal strain, a device having an In_{0.34}Ga_{0.73}N active layer on a zinc oxide epitaxial layer and zinc oxide substrate produces a peak wavelength of 646 nm (i.e., a red light emitting diode) with a medium amount of strain, and device having an In_{0.43}Ga_{0.57}N active layer on a zinc oxide epitaxial layer and zinc oxide substrate produces a peak wavelength of 765 nm (i.e., an infrared light emitting diode) with a large amount of strain.

Further, a device having In_{0.24}Ga_{0.76}N active layer on an aluminum magnesium epitaxial layer and scandium aluminum magnesium oxide (ScAlMgO₄) produces a peak wavelength of 539 nm (i.e., a yellow light emitting diode) with minimal strain, a device having In_{0.31}Ga_{0.69}N active layer on an aluminum magnesium epitaxial layer and scandium aluminum magnesium oxide (ScAlMgO₄) produces a peak wavelength of 611 nm (i.e., an orange light emitting diode) with a medium amount of strain, and a device having In_{0.4}Ga_{0.6}N active layer on an aluminum magnesium epitaxial layer and scandium aluminum magnesium oxide (ScAlMgO₄) produces a peak wavelength of 721 nm (i.e., an infrared light emitting diode) with large amount of strain. As will be appreciated by those skilled in the art, the lower the strain, the higher the device efficiency.

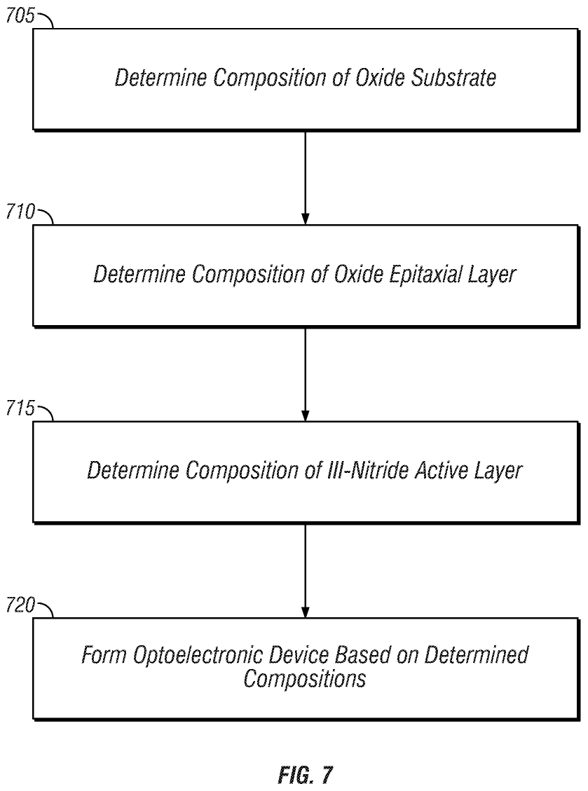

As will be appreciated from the discussion above, the disclosed optoelectronic device can be comprised of various materials in the substrate, epitaxial layer, and III-nitride active layers, as well as different compositions of materials within the layers or substrate. This allows the selection of materials based on cost, strain (and the corresponding efficiency increase or decrease), and desired use (e.g., selecting certain materials or compositions of materials to achieve a light emitting diode of a desired wavelength). FIG. 7 is a flowchart of a method of forming a III-nitride optoelectronic device using the various materials and material compositions according to embodiments. Initially, a composition of the oxide substrate 105 is determined (step 705). Next, the composition of the oxide epitaxial layer 110 is determined (step 710). As discussed above, the composition of the oxide epitaxial layer is based on the composition of the oxide substrate. The composition of the III-nitride active layer 115 is then determined (step 715). The composition of the III-nitride active layer 115 is based on the composition of the oxide epitaxial layer (i.e., to minimize strain), as well as the intended use of the device (e.g., selecting a certain amount of indium in an indium gallium nitride active layer). The optoelectronic device 100 is then formed based on the determined compositions of the oxide substrate 105, oxide epitaxial layer 110, and III-nitride active layer 115 step 720). The formation of the optoelectronic device 100 can be performed using the method discussed above in connection with FIG. 2.

Although FIG. 7 illustrates the determination of the compositions of different layers as being performed in a particular order, the determinations can be performed in a different order. For example, the composition of the III-nitride active layer 115 can be determined first, and then the compositions of either of the oxide epitaxial layer or the oxide substrate can then be determined, after which the composition of the other one of the oxide epitaxial layer or oxide substrate can be determined.

The disclosed embodiments provide a III-nitride optoelectronic device and method of production. It should be understood that this description is not intended to limit the invention. On the contrary, the exemplary embodiments are intended to cover alternatives, modifications and equivalents, which are included in the spirit and scope of the invention as defined by the appended claims. Further, in the detailed description of the exemplary embodiments, numerous specific details are set forth in order to provide a comprehensive understanding of the claimed invention. However, one skilled in the art would understand that various embodiments may be practiced without such specific details.

Although the features and elements of the present exemplary embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

1. An optoelectronic device, comprising:
ScAlMgO₄ substrate;
an oxide epitaxial layer arranged on the oxide substrate; and
a III-nitride active layer arranged on the oxide epitaxial substrate,
wherein the III-nitride active layer includes Al, In, Ga, and N.

2. The optoelectronic device of claim 1, wherein the oxide substrate and the oxide epitaxial layer both comprise same materials.

3. The optoelectronic device of claim 1, wherein the oxide epitaxial layer comprises at least one of zinc, gallium, magnesium, aluminum, calcium scandium, strontium, yttrium, cadmium, or indium.

4-5. (canceled)

6. The optoelectronic device of claim 1, wherein the oxide epitaxial layer is an n-type doped layer.

7. The optoelectronic device of claim 1, wherein the oxide substrate and the oxide epitaxial layer comprise zinc oxide.

8. The optoelectronic device of claim 1, wherein the III-nitride active layer has a peak emission wavelength in the range of 530 to 730 nm.

9. The optoelectronic device of claim 8, wherein the III-nitride layer comprises InₓGa₁₋ₓN, with x being larger or equal to 0 and smaller or equal to 1.

10. The optoelectronic device of claim 9, wherein the III-nitride layer comprises In_{0.27}Ga_{0.73}N or In_{0.19}Ga_{0.81}N.

11. A method of forming an optoelectronic device, the method comprising:
forming an oxide epitaxial layer on an oxide substrate, wherein the oxide substrate includes Sc, Al, and Mg; and
forming a III-nitride active layer on the oxide epitaxial layer, wherein the III-nitride active layer includes Al, In, Ga, and N.

12. The method of claim 11, wherein the oxide epitaxial layer and the III-nitride active layer are formed in a growth chamber.

13. The method of claim 12, wherein during the formation of the oxide epitaxial layer in the growth chamber, an atomically smooth surface is formed at an interface between the oxide substrate and the oxide epitaxial layer.

14. The method of claim 11, wherein the oxide substrate, oxide epitaxial layer and the III-nitride active layer are formed in a common growth chamber during a continuous growth process.

15. The method of claim 14, wherein the oxide substrate, oxide epitaxial layer and the III-nitride active layer are formed in the common growth chamber using metal-organic chemical vapor deposition.

16. A method of forming an optoelectronic device, the method comprising:
determining a composition of an oxide substrate, wherein the oxide substrate includes Sc, Al, and Mg;
determining a composition of an oxide epitaxial layer based on the determined composition of the oxide substrate;
determining a composition of a III-nitride active layer based on the determined composition of the oxide epitaxial layer to minimize a lattice mismatch between the III-nitride active layer and the oxide epitaxial layer, wherein the III-nitride active layer includes Al, In, Ga, and N so that the III-nitride active layer has a peak emission wavelength in a range of 530 to 730 nm; and
forming the optoelectronic device having an oxide epitaxial layer on the oxide substrate and the III-nitride active layer on the oxide epitaxial layer using the determined compositions of the oxide substrate, oxide epitaxial layer, and III-nitride active layer.

17. The method of claim 16, wherein the oxide epitaxial layer and the III-nitride active layer are formed in a growth chamber.

18. The method of claim 17, wherein during the formation of the oxide epitaxial layer in the growth chamber, an atomically smooth surface is formed at an interface between the oxide substrate and the oxide epitaxial layer.

19. The method of claim 16, wherein the oxide substrate, oxide epitaxial layer and the III-nitride active layer are formed in a common growth chamber during a continuous growth process.

20. The method of claim 19, wherein the oxide substrate, oxide epitaxial layer and the III-nitride active layer are formed in the common growth chamber using metal-organic chemical vapor deposition.
